(19) United States
(12) Patent Application Publication
(10) Pub. No.: US 2010/0079555 A1
(43) Pub. Date: Apr. 1, 2010

(54) LEAD-CONTAINING PEROVSKITE-TYPE OXIDE FILM AND METHOD OF PRODUCING THE SAME, PIEZOELECTRIC DEVICE USING A LEAD-CONTAINING PEROVSKITE-TYPE OXIDE FILM, AS WELL AS LIQUID EJECTING APPARATUS USING A PIEZOELECTRIC DEVICE

(76) Inventor: Takami ARAKAWA, Kanagawa (JP)

Correspondence Address: BIRCH STEWART KOLASCH & BIRCH, PO BOX 747, FALLS CHURCH, VA, 22040-0747, US

(21) Appl. No.: 12/569,735

(22) Filed: Sep. 29, 2009

(30) Foreign Application Priority Data
Sep. 30, 2008 (JP) 2008-253504

(51) Int. Cl. B41J 2/045; H01L 41/187; H01L 41/24; C04B 35/462; C23C 14/34; C23C 16/513

(52) U.S. Cl. 347/68; 310/358; 427/100; 428/220; 252/62.9 PZ; 204/192.18; 427/576; 29/25.35

(57) ABSTRACT

Provided is a lead-containing perovskite-type oxide film having principally (100) and/or (001) orientation and containing lead as a chief component, which is over 2 μm thick and exhibits such hysteresis characteristics that two coercive fields are both positive. A method of producing such an oxide film, a piezoelectric device including such an oxide film, and a liquid ejecting apparatus provided with such a piezoelectric device are also provided.

The entire contents of the documents cited in this specification are incorporated herein by reference.

### BACKGROUND OF THE INVENTION

The present invention relates to a lead-containing perovskite-type oxide film with a perovskite-type crystal structure and a method of producing such an oxide film, to a piezoelectric device including a piezoelectric member composed of a lead-containing perovskete-type oxide film, as well as to a liquid ejecting apparatus provided with such a piezoelectric device.

A piezoelectric device including a piezoelectric member with such piezoelectric properties that the member expands or contracts as the intensity of an electric field applied is increased or deceased, and electrodes for applying an electric field to the piezoelectric member is used for a piezoelectric actuator to be mounted on an inkjet recording head, for instance. In order to carry out a high-resolution and high-speed printing with an inkjet recording head, density increase in piezoelectric device is necessary. For the density increase, reducing piezoelectric devices in thickness is being contemplated, whereupon piezoelectric members used in the devices are preferably of a thin film type from the viewpoint of processing accuracy.

It is also necessary for a high-resolution printing to use ink of high viscosity. Piezoelectric devices are required accordingly to have higher piezoelectric performances enabling ejection of a highly viscose ink. There is a need for piezoelectric devices which include piezoelectric members with reduced film thicknesses and are excellent in piezoelectric properties.

In recent years, it is expected that a lead-containing perovskite-type oxide film with a perovslite-type crystal structure (hereafter also referred to simply as “oxide film”), such as a lead-containing thin film based on lead zirconate titanate (PZT), is used for a memory, a ferroelectric memory for instance, or a liquid ejecting apparatus such as an inkjet head.

Control of the direction of polarization in a piezoelectric member composed of such an oxide film as above is well known as effective at improving piezoelectric properties of the member.

In piezoelectric members, the direction of polarization is readily detected by ferroelectric hysteresis measurement, and the directability of polarization can be evaluated based on two coercive fields in the hysteresis characteristics.

It is described in JP 2003-243741 A that piezoelectric properties of a piezoelectric member (piezoelectric layer or film) can be improved by shifting the hysteresis characteristics of the member such that two coercive fields Ec are of the same polarity.

In the case of the piezoelectric member as disclosed in JP 2003-243741 A, the film in itself is under stress, or an internal stress is being generated in the film, so as to greatly shift the coercive fields Ec of the piezoelectric member. Specifically, the piezoelectric member is provided by sequentially forming two layers with different lattice constants to utilize the lattice distortion due to the crystal lattice mismatch between the two layers.

JP 2001-284670 A discloses a piezoelectric member (piezoelectric film) having a film thickness of 1 to 10 μm and a relative dielectric constant of 150 to 500, or a molar ratio of lead to the cations being constituents of the piezoelectric member other than lead ranging from 1.1 to 1.5, and states that the disclosed piezoelectric member has been improved in piezoelectric properties.

It is described in JP 2005-123421 A that higher piezoelectric properties are expected from the piezoelectric member (piezoelectric film) which exhibits such a shift in polarization (namely, shift of coercive fields in the hysteresis characteristics) that the polarization shift ΔEc=∥Ec⁺|−|Ec⁻∥/(|Ec⁺|+|Ec⁻|)(where Ec⁺ is the coercive field of a piezoelectric material on the positive field side, and Ec⁻ is that on the negative field side) is as specified in value. JP 2005-123421 A discloses the piezoelectric member whose polarization shift ΔEc satisfies the relation ⅓ΔEc<1 as a piezoelectric member with those piezoelectric properties which are less dependent on the electric field intensity, and are high enough even at lower electric field intensities.

The piezoelectric member as disclosed in JP 2003-243741 A has been improved in piezoelectric properties indeed, but its fabrication process is disadvantageously complicated as compared with the process for a piezoelectric member with one layer because the disclosed piezoelectric member needs to be provided by sequentially forming two different films (two films of different materials) in order to greatly shift the coercive fields Ec in the hysteresis characteristics of the member. In addition, contamination may occur between two layers of different films sequentially formed. The films are to be formed individually so that a dedicated production unit is required for each layer, which increases the manufacturing costs.

By the way, it is well known that even the hysteresis characteristics of a piezoelectric member exhibiting basically no shift in polarization is greatly shifted if a stress is applied to the member. For such a shift of the hysteresis characteristics, a considerable warpage with, for instance, R=30 cm, namely a considerable stress, is required (see Applied Physics Letters, Vol. 83, Issue 4, pp. 728-730 (2003)).

Cracks may accordingly be caused in the piezoelectric member as disclosed in JP 2003-243741 A due to the thermal stress during film deposition if the member is too thick. For this reason, the piezoelectric member as disclosed in JP 2003-243741 A is limited in film thickness to 500 nm to 2,000 nm (2 μm), with a thickness of more than 2 μm being very hard to attain.

In the piezoelectric member as disclosed in JP 2001-284670 A, a perovskite thin film, which is free of impurities and contains excess lead as shown in FIG. 3 of the cited document, is deposited by specifying the molar ratio of lead to other cations (Zr and Ti) in the member to 1.1 to 1.5. No description, however, is made in the document about the polarization shift.

There are a great many examples of the perovskite thin film containing excess lead, in which excess lead is precipitated in the form of lead oxide or a pyrochlore compound. In contrast, examples of the perovskite thin film which is free of impurities and contains excess lead, such as the piezoelectric member as disclosed in JP 2001-284670 A, are not large in number. Nevertheless, the piezoelectric member composed of the perovskite thin film with a perovskite structure that is free of impurities and contains excess lead owns its examples apart from JP 2001-284670 A. For instance, a piezoelectric member may be mentioned which is composed of the perovskite thin film in which excess lead is implanted in site B as a tetravalent lead (Pb⁴⁺) (see Physical Review B 66, 064102-1-8 (2002); Integrated Ferroelectrics, Vol. 36, pp. 53-62 (2001)). In any of such examples, however, the polarization shift in a piezoelectric member is in no way discussed.

Finally, it is disclosed in JP 2005-123421 A that the piezoelectric properties of a piezoelectric member can be made less dependent on the electric field intensity and high enough even at lower electric field intensities by controlling the polarization shift ΔEc of the member so that it may be equal to or larger than ⅓ but smaller than 1, so as to improve the properties. In the cited document, however, two coercive fields Ec in the hysteresis characteristics of a piezoelectric member are so defined that one of them may be on the positive field side (Ec⁺) and the other on the negative field side (Ec⁻), and neither consideration is given to nor disclosure is made on those piezoelectric members whose two coercive fields are both on the positive or negative field side.

### SUMMARY OF THE INVENTION

It is therefore an object of the present invention to solve the above problems involved with the prior art and provide a lead-containing perovskite-type oxide film with improved piezoelectric properties, which allows a piezoelectric member having two coercive fields in its hysteresis characteristics both defined on the positive field side, and being over 2 thick with no stress generated therein.

It is another object of the present invention to provide a method of producing a lead-containing perovskite-type oxide film which enables a stable production of such a lead-containing perovskite-type oxide film as above, a piezoelectric device using a piezoelectric member composed of such a lead-containing perovskite-type oxide film as above, and a liquid ejecting apparatus using such a piezoelectric device.

In order to achieve the objects as above, the present inventor reviewed many prior art techniques including those disclosed in JP 2003-243741 A, JP 2001-284670 A and JP 2005-123421 A, and conducted intensive studies on lead-containing perovskite-type oxide films as piezoelectric members having high piezoelectric properties. As a result, it has been found that the stress indispensable for shifting polarization to obtain high piezoelectric properties in JP 2003-243741 A makes it impossible to form a piezoelectric member having no cracks caused therein in spite of a film thickness of more than 2 μm. In other words, it has been found that the formation of a piezoelectric member with a film thickness of more than 2 μm, which is not possible in JP 2003-243741 A, is made possible by shifting polarization without application of such a large stress as causes cracks in the member, which is indispensable in JP 2003-243741 A. In films with large lead amounts, for instance, polarization is shifted even under a smaller stress, enabling to form a piezoelectric member with a film thickness of more than 2

It has thus been found that the lead-containing perovskite-type oxide film, which exhibits such hysteresis characteristics that two coercive fields Ec are both on the positive field side and in which any large stress is not generated in spite of a film thickness of more than 2 μm, can be obtained by producing the perovskite thin film, or lead-containing perovskite-type oxide film, which is free of heterophases such as a lead oxide or pyrochlore phase and contains excess lead. The present invention has been accomplished on the basis of these findings.

It should be noted that the mechanism of the shift in polarization (shift of coercive fields) in the lead-containing perovskite-type oxide film of the present invention is not clarified yet. According to the investigation by the inventor, the stress in the inventive oxide film is about 200 MPa, which is very small as compared with a stress of about 1 GPa required for the polarization control with stress as in JP 2003-243741 A. It can therefore be considered that the shift in polarization in the oxide film of the present invention is induced by something other than stress, by defect dipoles due to point defects, for instance.

A first aspect of the present invention provides a lead-containing perovskite-type oxide film having principally (100) and/or (001) orientation and containing lead as a chief component, which is over 2 μm thick and exhibits such hysteresis characteristics that two coercive fields are both positive.

It is preferable that the molar ratio of lead to other cations in the oxide film is 1.07 or more, and substantially no impurity phase is detected in the oxide film by θ/2θ X-ray diffractometry. In this regard, the term “lead amount” used herein refers to the molar ratio of lead as a cation to other cations in an oxide film.

The present invention also provides a lead-containing perovskite-type oxide film having principally (100) and/or (001) orientation and containing lead as a chief component, wherein: the oxide film exhibits such hysteresis characteristics that two coercive fields are both positive; the molar ratio of lead to other cations in the oxide film is 1.07 or more; and substantially no impurity phase is detected in the oxide film by θ/2θ X-ray diffractometry.

The lead-containing perovskite-type oxide film of the present invention is a film based on one or more lead-containing perovskite-type oxides.

In addition, the lead-containing perovskite-type oxide film of the present invention has principally (100) and/or (001) orientation. In the present invention, “having principally a given orientation” is defined as having a given orientation with a degree of orientation F of 80% or more as measured by Lotgerling method.

Preferably, the lead-containing perovskite-type oxide film of the present invention has 90% or more (100) and/or (001) orientation.

The degree of orientation F is expressed by the following equation (i):

F(%)=(P−P₀)/(1−P₀)×100 (i)

where P is the ratio of the sum of reflection intensities from specified orientation planes in a thin film to be measured in degree of orientation F (hereafter also referred to simply as “thin film”) to the sum of all the reflection intensities with respect to the thin film.

If the degree of orientation F is to be found for (100) orientation of the thin film, for instance, P is the ratio of the sum ΣI(100) of the reflection intensities I(100) from the (100) planes in the thin film to the sum ΣI(hkl) of the reflection intensities I(hkl) from the individual crystal planes (hkl) in the thin film, namely {ΣI(100)/ΣI(hkl)}.

To be more specific: if the degree of orientation F is to be found for (100) orientation of the thin film with a perovskite structure in which (100), (110) and (111) orientations are mixed together, P is defined as I(100)/[I(100)+I(101)+I(110)+I(111)].

While a piezoelectric PZT material may be tetragonal or rhombohedral in crystal system, “the (100) plane” mentioned herein is to be considered as either of the (100) and (001) orientation planes. The same applies to the (110) and (101) planes.

On the other hand, P₀ denotes the value of P which will be obtained from the thin film oriented randomly in whole. In other words, if the thin film is oriented randomly in whole, P=P₀ and the thin film has a degree of orientation F of 0%. Conversely, if the thin film is oriented orderly in whole, P=1 and the thin film has a degree of orientation F of 100%.

The lead-containing perovskite-type oxide film (hereafter also referred to simply as “oxide film”) of the present invention differs from any of the above piezoelectric members (films) disclosed in JP 2003-243741 A, JP 2001-284670 A and JP 2005-123421 A as follows.

Firstly, in the piezoelectric member of JP 2003-243741 A, an internal stress is generated in a film provided by sequentially forming two layers with different lattice constants and compositions so as to shift two coercive fields Ec greatly, as described before. The film thickness cannot be increased because cracks may be caused by a large internal stress, so that the piezoelectric member is limited in thickness to 500 nm to 2,000 nm (2 μm).

In contrast, the oxide film of the present invention does not need to have an internal stress generated therein in order to shift two coercive fields Ec in its hysteresis characteristics. According to the present invention, shifting both of the two coercive fields Ec positively (to the positive field side) is compatible with making the oxide film over 2 thick, leading to a film capable of increased displacement. The oxide film of the present invention is thus distinguished from the piezoelectric member of JP 2003-243741 A.

Secondly, the piezoelectric member of JP 2001-284670 A is a piezoelectric member containing lead so that the molar ratio of lead to other cations (Zr and Ti) in the member may be 1.1 to 1.5, as described before.

In the oxide film of the present invention, two coercive fields are both positive, and the molar ratio of lead to other cations is preferably 1.07 or more. Since there is no description in JP 2001-284670 A about hysteresis characteristics of the disclosed piezoelectric member or coercive fields found in them, the piezoelectric member of JP 2001-284670 A is not considered to correspond to the inventive oxide film having such hysteresis characteristics as above. If the molar ratio of lead to other cations in the oxide film of the present invention is 1.07 or more, the piezoelectric member of JP 2001-284670 A and the inventive oxide film then differ from each other also in lead amount.

Thirdly, in the piezoelectric member of JP 2005-123421 A, one of the two coercive fields (Ec) in its hysteresis characteristics is positive (Ec⁺) and the other negative (on the negative field side) (Ec⁻), and the polarization shift ΔEc of the member calculated from the two coercive fields (Ec⁺ and Ec⁻) satisfies the relation expressed by the inequality ⅓ΔEc<1, as described before.

In the case of the oxide film of the present invention, two coercive fields are both positive, which distinguishes the inventive oxide film from the piezoelectric member of JP 2005-123421 A.

Also in order to achieve the objects as above, a second aspect of the present invention provides a method of producing a lead-containing perovskite-type oxide film, which comprises controlling upon production of the lead-containing perovskite-type oxide film according to the first aspect of the present invention the lead amount of the oxide film during film deposition. The lead amount is defined in the present invention as the molar ratio of lead as a cation to other cations in the oxide film.

In the method of the present invention, it is preferable that a lead-containing perovskite-type oxide film is deposited by sputtering, and the lead amount is controlled by controlling the film deposition temperature during film deposition, the plasma energy applied to a substrate for film deposition during film deposition, the partial pressure of oxygen during film deposition, the power supplied during film deposition, or the film deposition pressure during film deposition.

Also in order to achieve the objects as above, a third aspect of the present invention provides a piezoelectric device comprising: a piezoelectric member constituted by the lead-containing perovskite-type oxide film according to the first aspect of the present invention; and a lower electrode and an upper electrode formed on the lower and upper sides of the piezoelectric member, respectively, in order to apply voltages to the piezoelectric member, the lead-containing perovskite-type oxide film as the piezoelectric member having a lead amount near the interface with the lower electrode that is equal to or larger than the lead amount of the oxide film as a whole.

Also in order to achieve the objects as above, a forth aspect of the present invention provides a liquid ejecting apparatus comprising: the piezoelectric device according to the third aspect of the present invention; a liquid reservoir for storing liquid; and a liquid spout through which the liquid in the liquid reservoir is ejected to outside by applying a voltage to the piezoelectric device.

### BRIEF DESCRIPTION OF THE DRAWINGS

FIG. 1 is a graph showing the relation between the shift of hysteresis of an oxide film according to an embodiment of the present invention and the ratio of lead as a cation to other cations in the film.

FIG. 2 is a cross-sectional view showing the structure of an inkjet head using an oxide film according to the embodiment of the present invention.

FIG. 3 is a diagram showing the results of X-ray diffractomtry on the PZT films obtained in a working example of the present invention and a comparative example.

FIG. 4 is a diagram showing the hysteresis characteristics of the PZT films obtained in the working example of the present invention and the comparative example.

### DETAILED DESCRIPTION OF THE INVENTION

The following is a detailed description on the lead-containing perovskite-type oxide film of the present invention and the method of producing it, the piezoelectric device of the present invention using the lead-containing perovskite-type oxide film, as well as the liquid ejecting apparatus of the present invention using the piezoelectric device.

The lead-containing perovskite-type oxide film (or simply, oxide film) of the present invention is an oxide film having principally (100) and/or (001) orientation and containing lead as a chief component, and is characterized by a film thickness of more than 2 μm and two coercive fields (Ec) in its hysteresis characteristics which are both positive.

In addition, in a preferred embodiment of the oxide film of the present invention, the molar ratio of lead as a cation to other cations in the film is 1.07 or more, and substantially no impurity phase is detected in the film by θ/2θ X-ray diffractometry.

As described above, the oxide film of the present invention is the oxide film with a perovskite-type crystal structure in which the (100) and/or (001) orientation is predominant, and the degree of orientation F thereof should be 80% or more as measured by the Lotgerling method. Owing to a predominant (100) and/or (001) orientation, the oxide film of the present invention is excellent in piezoelectric and ferroelectric performances.

Preferably, the oxide film of the present invention has 90% or more (100) and/or (001) orientation. The definition of the degree of orientation F is as given before.

The oxide film of the present invention does not have a large stress generated therein, which allows a film thickness of more than 2 μm. In fact, the stress generated in the oxide film of the present invention is usually about 200 MPa. If a piezoelectric member with two coercive fields (Ec) in its hysteresis characteristics being both positive is to be provided by controlling the member in polarization with an internal stress therein, as is the case with JP 2003-243741 A, the internal stress must be about 1 GPa. Such a large internal stress in a piezoelectric member may cause cracks, and the thickness of the piezoelectric member provided cannot be large but 2 μm or less.

According to the present invention, it it possible to reduce internal stresses in a piezoelectric member and, at the same time, make both of the two coercive fields (Ec) in the hysteresis characteristics of the member positive, so as to provide a piezoelectric member composed of an oxide film having a thickness of more than 2 μm.

It should be noted that an oxide film (lead-containing piezoelectric oxide film) having a thickness of 2 μm or less cannot be displaced adequately to piezoelectric device applications. For this reason, the oxide film of the present invention needs to be over 2 μm thick, with a thickness of 3.0 μm or more being preferred. The thickness of the oxide film of the present invention has no particular upper limit because a thicker film is readily formed by increasing the film deposition time. An exemplary upper limit may be put at about 20 μm.

The oxide film of the present invention should exhibit such hysteresis characteristics that two coercive fields (Ec) are both positive. As such, the oxide film of the present invention has high piezoelectric properties enabling a marked displacement of the film with a large piezoelectric constant when a negative voltage (negative electric field) is applied thereto. Consequently, the piezoelectric device of the present invention stably effects a marked displacement when driven by the application of a negative voltage (on the negative field side) and, moreover, is drivable with reduced power consumption.

Generally, such a piezoelectric member as the oxide film of the present invention is used in the form of a piezoelectric device having a lower electrode, the piezoelectric member in question, and an upper electrode layered sequentially in this order, and is driven through the lower and upper electrodes, with one of them serving as the ground electrode to which a fixed voltage of 0 V is applied and the other serving as the address electrode to which a varying voltage is applied. For a convenient driving of the piezoelectric member, it is general to use the lower electrode as the ground electrode and the upper electrode as the address electrode. In this connection, a state in which “a negative electric field is applied to the piezoelectric member” means that of a negative voltage being applied to the address electrode. Similarly, a state in which “a positive electric field is applied to the piezoelectric member” means that of a positive voltage being applied to the address electrode.

For the application of negative electric fields, the driver IC used to drive the upper electrode may be the one for negative voltage application, or alternatively, a general-purpose driver IC for positive voltage application may be employed by patterning the lower electrode to obtain an address electrode and using the upper electrode as a ground electrode.

In an embodiment of the present invention, it is preferable that the molar ratio of lead as a cation to other cations in the oxide film is 1.07 or more, and substantially no impurity phase is detected in the film by θ/2θ X-ray diffractometry.

The oxide film of the present invention may also be an oxide film having principally (100) and/or (001) orientation and containing lead as a chief component, wherein: the oxide film exhibits such hysteresis characteristics that two coercive fields (Ec) are both positive; the molar ratio of lead to other cations in the oxide film is 1.07 or more; and substantially no impurity phase is detected in the oxide film by θ/2θ X-ray diffractometry.

The oxide film of the present invention is a piezoelectric member having excellent piezoelectric properties as described above, and is preferably an oxide film containing Pb, Zr, Ti and O, more preferably a thin film of lead zirconate titanate (PZT) represented by chemical formula (2):

Pbₓ(Zr_{1-y},Ti_{y})_{1-z}Nb_{z}O_{δ} (2).

In chemical formula (2), Pb is a site A element, Zr, Ti and Nb are site B elements, and O is oxygen atom. It is preferable that x, y, and z in the formula are defined as 1.07≦x, 0≦y≦1, and 0≦z≦0.25, respectively, with 1.07≦x≦1.20, 0.4≦y≦0.6, and 0.1≦z≦0.2 being more preferable. While it is standard that δ is equal to 3, δ may represent any other number as long as the material has a perovskite structure.

In the above chemical formula (2), x is the amount of lead contained in the oxide film, that is to say, the ratio (molar ratio) of lead to the cations other than lead in the oxide film. Consequently, in the present invention, the lead amount is represented by x in chemical formula (2) that can be described as x=Pb/(Zr+Ti+Nb).

In order to provide the oxide film of the present invention as an oxide film with a perovskite-type crystal structure in which the (100) and/or (001) orientation is predominant, it is preferable to specify the content x of Pb at site A in chemical formula (2) to 1.07≧x, more preferably 1.07≦x≦1.20, as well as specify the value of y, with which the composition ratio between Ti and Zr at site B is indicated, to 0≦y≦1, and the value of z, with which the composition ratio between Ti and Zr in combination and Nb, all at site B, is indicated, to 0≦z≦0.25. The oxide film of the present invention thus provided as an oxide film with a perovskite-type crystal structure in which the (100) and/or (001) orientation is predominant is excellent in piezoelectric and ferroelectric performances.

It is more preferable to determine the value of y such that the composition of the material approximates to the morphotropic phase boundary (MPB) composition at the phase transition point between tetragoal phase and rhombohedral phase because higher ferroelectric performances are attained. Specifically, the value of y is preferably 0≦y≦1, more preferably 0.4≦y≦0.6, and even more preferably 0.47≦y≦0.57. The value of z is preferably 0≦z≦0.25, and more preferably 0.1≦z≦0.2.

The oxide film of the present invention may also be a film of an oxide with a perovskite-type crystal structure as a combination of PZT as above and other ferroelectric material. Preferred examples of the oxide include PNN (lead niccolate niobate)-PZT and PZN (lead zincate niobate)-PZT.

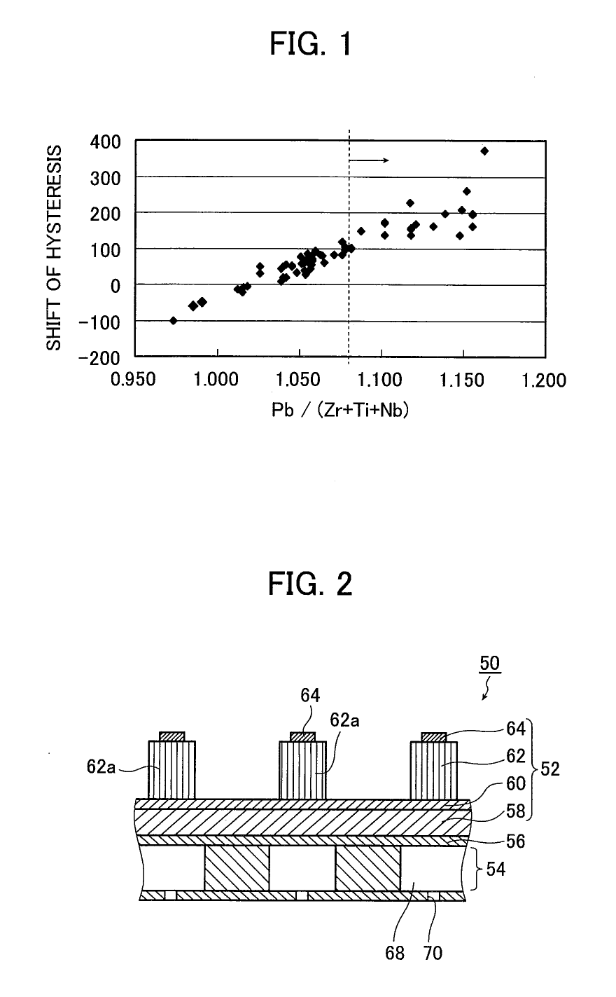

FIG. 1 is a graph showing the relation between the shift of hysteresis and the lead amount (molar ratio) of an oxide film that was found by the inventor in Example 1 as described later with respect to a large number of oxide films including the oxide film of the present invention.

With the larger (in value) out of two coercive fields in the hysteresis characteristics of an oxide film being represented by Ec₁ and the smaller by Ec₂, the shift of hysteresis D (%) is defined as a value obtained by multiplying the value (Ec₁+Ec₂)/(Ecᵢ−Ec₂) by 100.

D(%)=(Ec₁+Ec₂)/(Ecᵢ−Ec₂)×100

In the present invention, two coercive fields are both positive, namely Ec₁>Ec₂>0, so that the shift of hysteresis D exceeds 100%.

In other words, two coercive fields of the oxide film of the present invention are both positive if the shift of hysteresis D exceeds 100%. It is seen from FIG. 1 accordingly that the lead amount of the oxide film may be specified to 1.07 or more as one means to make both the coercive fields positive.

According to the present invention, the piezoelectric member can be provided which has ferroelectric properties owing to its film structure composed of numerous columnar crystals. The film structure whose numerous columnar crystals extend non-parallel to the substrate surface of a piezoelectric device will bring about an oriented film, which is uniform in crystal orientation, as a preferable film because of its high piezoelectric properties.

In this regard, there are several types of piezoelectric strain including:

(1) normal piezoelectric strain induced by electric fields, in which expansion or contraction occurs in the electric field-applying direction in accordance with the increase or decrease in the intensity of an electric field applied, with the electric field-applying direction being coincident with the vector component of the axis of spontaneous polarization;

(2) piezoelectric strain caused by a reversible turn of the axis of polarization at an angle other than 180° in accordance with the increase or decrease in the intensity of an electric field applied;

(3) piezoelectric strain allowed to occur by utilizing the change in volume based on the phase transition of crystals in accordance with the increase or decrease in the intensity of an electric field applied; and

(4) piezoelectric strain allowed to occur by utilizing the engineered domain effect, whereupon the oriented crystal structure, which includes a ferroelectric phase with a crystal orientability in the direction other than the direction of the axis of spontaneous polarization, is produced using a material having a property of phase transition upon application of an electric field thereto, so as to achieve a larger strain. (In the case of utilizing the engineered domain effect, the piezoelectric member may be driven under the conditions causing or not causing phase transition).

A desired piezoelectric strain can be attained by employing the above piezoelectric strains (1) to (4) alone or in combination. The piezoelectric strains (1) to (4) are each obtained by producing an oriented crystal structure in response to the principles of occurrence of the relevant strain. It is therefore preferable for the achievement of high piezoelectric effects that a ferroelectric film has a crystal orientability. In the case of a ferroelectric film based on PZT with an MPB composition, for instance, the film is preferably of a structure with (100)-oriented columnar crystals.

Columnar crystals may grow in any direction with respect to the substrate surface, almost perpendicularly thereto, diagonally thereto, or the like, as long as the direction is non-parallel to the surface.

The mean diameter of numerous columnar crystals of which the piezoelectric member is composed is not particularly limited, while it is preferably 30 nm or more but 1 μm or less. If the mean diameter of columnar crystals is too small, the growth of crystals may be insufficient for a ferroelectric material, or desired ferroelectric (piezoelectric) performances may not be attained. On the other hand, the shape after patterning may be reduced in precision with too large a mean diameter.

It should be noted that the present invention is in no way limited to the embodiment as described above, in which the oxide film is over 2 μm thick and exhibits such hysteresis characteristics that two coercive fields are both positive, the molar ratio of lead as a cation to other cations in the film is 1.07 or more, and substantially no impurity phase is detected in the film by θ/2θ X-ray diffractometry. It is also possible that the oxide film of the present invention meets either of two conditions, one condition that the film is over 2 μm thick and exhibits such hysteresis characteristics that two coercive fields are both positive, and the other that the molar ratio of lead as a cation to other cations in the film is 1.07 or more, and substantially no impurity phase is detected in the film by θ/2θ X-ray diffractometry.

Next described is the inventive method of producing a lead-containing perovskite-type oxide film by which the oxide film of the present invention is produced.

Upon production of the oxide film of the present invention, the film deposition process to be used is not particularly limited as long as the lead amount of the oxide film is controlled during film deposition so that the film may contain excess lead, to thereby produce the oxide film of the present invention as described above. Exemplary processes include known ones such as sputtering, chemical vapor deposition (CVD), plasma CVD, pulse laser deposition (PLD), baking and quenching, annealing and quenching, thermal spraying and quenching, and sol-gel process. Among those, sputtering, RF sputtering in particular, is preferred because the film deposition rate is high and the crystalline films formed are of high quality.

In the present invention, film deposition processes not requiring heat equilibrium are preferred than those requiring heat equilibrium, such as the sol-gel process in which an additive inherently having a different valence from the matrix is hard to dope at a high concentration and it is necessary to take such special measures as use of a sintering aid or acceptor ions. The reason is that, in processes not requiring heat equilibrium, donor ions such as Nb ions are doped at a high concentration with no special measures taken.

Moreover, film deposition processes not requiring heat equilibrium such as sputtering can be performed at a relatively low temperature below the temperature at which Si and Pb are reacted with each other, so that it is possible with the processes not requiring heat equilibrium to deposit the oxide film of the present invention on a silicon (Si) substrate with good processability.

Factors influencing the properties of a film deposited by sputtering, RF sputtering in particular, may include the film deposition temperature, the plasma energy applied to the substrate surface during film deposition, the partial pressure of oxygen (amount of oxygen) in an atmosphere, the RF power supplied during film deposition, the film deposition pressure, the kind of the substrate, the composition of the undercoat previously deposited on the substrate, if any, the distance between the substrate and the target, the electron temperature and the electron density in the plasma, as well as the density and life of the active species in the plasma.

Among others, the film deposition temperature, the plasma energy applied to the substrate, the partial pressure of oxygen, the RF power supplied, and the film deposition pressure can be considered as critical for the control of the quality (properties) of the lead-containing piezoelectric film deposited, especially for the control of its lead amount.

Accordingly, while the method of controlling the lead amount of the inventive oxide film is not particularly limited, a preferred method includes controlling any of the film deposition temperature during the deposition of the oxide film, the plasma energy applied to the substrate during film deposition, the partial pressure of oxygen during film deposition, and the RF power or other power supplied during film deposition, or any combination thereof, in accordance with the film deposition process used.

The control of the lead amount may be carried out by previously determining the conditions for film deposition, such as the film deposition temperature, the plasma energy applied to the substrate, the partial pressure of oxygen, and the RF power or other power supplied, in a manner appropriate to the apparatus for the selected film deposition process such as sputtering, and so forth, and finding the relation between each of the various conditions and the lead amount so as to control the conditions for film deposition during the deposition of a piezoelectric member and thereby attain a desired lead amount.

In the method of producing the oxide film of the present invention, the film deposition rate is not limited, that is to say, the oxide film may be formed at any deposition rate, with a rate of 1 μm/h or more being preferred from the viewpoint of throughput.

The structures of a piezoelectric device using the oxide film produced as above and a liquid ejecting apparatus (hereafter also referred to as “inkjet head”) provided with the piezoelectric device are then described.

FIG. 2 is a cross-sectional view of a principal part of the inkjet head using the piezoelectric device according to an embodiment of the present invention (cross-sectional view in the direction along the thickness of the piezoelectric device). For a good visibility, elements are shown appropriately at different scales from the real ones.

As shown in FIG. 2, an inkjet head 50 of the present invention includes a piezoelectric device 52 of the present invention, a plurality of ink storing/ejecting portions 54, and a diaphragm 56 provided between the piezoelectric device 52 and the ink storing/ejecting portions 54.

The piezoelectric device 52 of the present invention is initially to be described.

As seen from the figure, the piezoelectric device 52 is a device composed of a substrate 58, as well as a lower electrode 60, a piezoelectric member 62 and upper electrodes 64 sequentially layered on the substrate 58, in which electric fields will be applied to the piezoelectric member 62 consisting of the lead-containing perovskite-type oxide film of the present invention in the direction of its thickness through the lower and upper electrodes 60 and 64.

The material for the substrate 58 is not particularly limited, and examples thereof include silicon, glass, stainless steel (JIS classification: SUS series), yttrium-stabilized zirconia (YSZ), alumina, sapphire, and silicon carbide. It is also possible to use a laminated substrate, such as an SOI substrate composed of the silicon substrate on which a SiO₂ film is formed, as the substrate 58.

The lower electrode 60 is formed on almost the entire surface of the substrate 58, and the piezoelectric member 62 is formed on the lower electrode 60. The piezoelectric member 62 is patterned such that a plurality of protruded portions 62a each shown in the figure as extending from the front to the back of the figure plane are arranged at intervals in the form of stripes. The upper electrode 64 is formed on each protruded portion 62a.

The pattern of the piezoelectric member 62 is not limited to the shown one but designed appropriately. The piezoelectric member 62 may also be formed as one continuous film, but it is preferable to form the member 62 with the pattern in which a plurality of protruded portions 62a are separated from one another because the protruded portions 62a each expand or contract smoothly, leading to a more considerable expansion or contraction of the piezoelectric member 62.

The material to be used in the lower electrode 60 as a chief component is not particularly limited, and examples thereof include such metals and metal oxides as Au, Pt, Ir, IrO₂, RuO₂, LaNiO₃ and SrRuO₃, as well as combinations thereof.

The material to be used in the upper electrodes 64 as a chief component is not particularly limited, and examples thereof include the above exemplary materials for the lower electrode 60, electrode materials commonly used in the semiconductor process, such as Al, Ta, Cr and Cu, as well as combinations thereof.

The piezoelectric member 62 is the inventive oxide film as described before, and has a lead amount near the interface with the lower electrode 60 that is equal to or larger than the mean lead amount of the piezoelectric member 62 as a whole.

The lower and upper electrodes 60 and 64 each have a thickness of, for instance, about 200 nm. The film thickness of the piezoelectric member 62 is not particularly limited, but is generally 1 μm or more, 1 to 5 μm, for instance.

The inkjet head 50 as shown in FIG. 2 has the ink storing/ejecting portions 54 attached through the diaphragm 56 to the lower surface of the substrate 58 of the piezoelectric device 52 with the above configuration Each ink storing/ejecting portion 54 includes an ink compartment (ink reservoir) 68 for storing ink, and an ink spout (nozzle) 70 through which the ink in the ink compartment 68 is ejected to outside. There are a plurality of ink compartments 68 corresponding to the protruded portions 62a of the piezoelectric member 62 in number and pattern. In other words, the inkjet head 50 includes a plurality of ink storing/ejecting portions 54, and the protruded portion 62a, the upper electrode 64, the ink compartment 68 and the ink nozzle 70 are provided for each ink storing/ejecting portion 54. On the other hand, the lower electrode 60, the substrate 58 and the diaphragm 56 are each common to a plurality of ink storing/ejecting members 54, to which, however, the present invention is not limited. The elements 60, 58 and 56 may each be provided for each ink storing/ejecting portion 54, or alternatively, for every several portions 54.

In the inkjet head 50, electric fields applied to the protruded portions 62a of the piezoelectric device 52 are increased or decreased in intensity by a conventional driving method for each portion 62a so as to expand or contract the relevant portion 62a, and thereby control ink ejection from the corresponding ink compartment 68 in timing and amount.

A detailed description has been made as above on the lead-containing perovskite-type oxide film of the present invention and the method of producing it, the piezoelectric device of the present invention including a piezoelectric member consisting of the lead-containing perovskite-type oxide film, as well as the liquid ejecting apparatus of the present invention provided with the piezoelectric device, referring to a variety of embodiments.

The present invention, however, is in no way limited to the above embodiments, and various improvements and design modifications may of course be made without departing from the spirit and scope of the invention.

### EXAMPLE

The present invention is explained in more detail in reference to a specific example thereof and the accompanying drawings as well. As a matter of course, the present invention is not limited to the example below.

### Example 1

An RF sputtering apparatus (MPS-type sputtering apparatus for ferroelectric film deposition from ULVAC, Inc.) was used as a film deposition apparatus.

The target material used was a sintered body of 120 mm in diameter having a composition Pb_{1.3}(Zr_{0.52}Ti_{0.48})O₃.

A substrate was prepared in advance by sequentially forming on a Si wafer a 20 nm-thick layer of Ti and a 150 nm-thick layer of Ir having principally (111) orientation.

The distance between the target material and the substrate was 60 mm.

At a substrate temperature of 420° C., Ar+O₂ (2.5%) gas was introduced into a vacuum vessel of the RF sputtering apparatus and the pressure in the vessel was stabilized at 0.5 Pa. An RF power of 500 W was then supplied in the vacuum vessel to deposit a film at a temperature of 420° C. until a PZT film (lead zirconate titanate film) of 4 μm in thickness was obtained.

The thickness of the PZT film deposited was measured using a stylus surface profiler Dektak 6M from ULVAC, Inc. The PZT film had a thickness of 4 μm.

In addition, the molar ratio of lead as a cation to other cations in the PZT film was determined by conducting X-ray fluoroscence (XRF) analysis using an Axios X-ray fluoroscence spectrometer from PANalytical B. V. The molar ratio of lead in the PZT film was 1.12.

The above results are summarized in Table 1.

TABLE 1

| | Film | Molar ratio | Shift of |
|---|---|---|---|
| | thickness | of lead | hysteresis D (%) |
| Example 1 | 4 μm | 1.12 | 170% |
| Comparative | 4 μm | 1.04 | 45% |
| Example 1 | | | |

The PZT film was subjected to the X-ray diffractometry based on θ/2θ measurement by using an Ultima X-ray diffractometer for thin film evaluation from Rigaku Corporation.

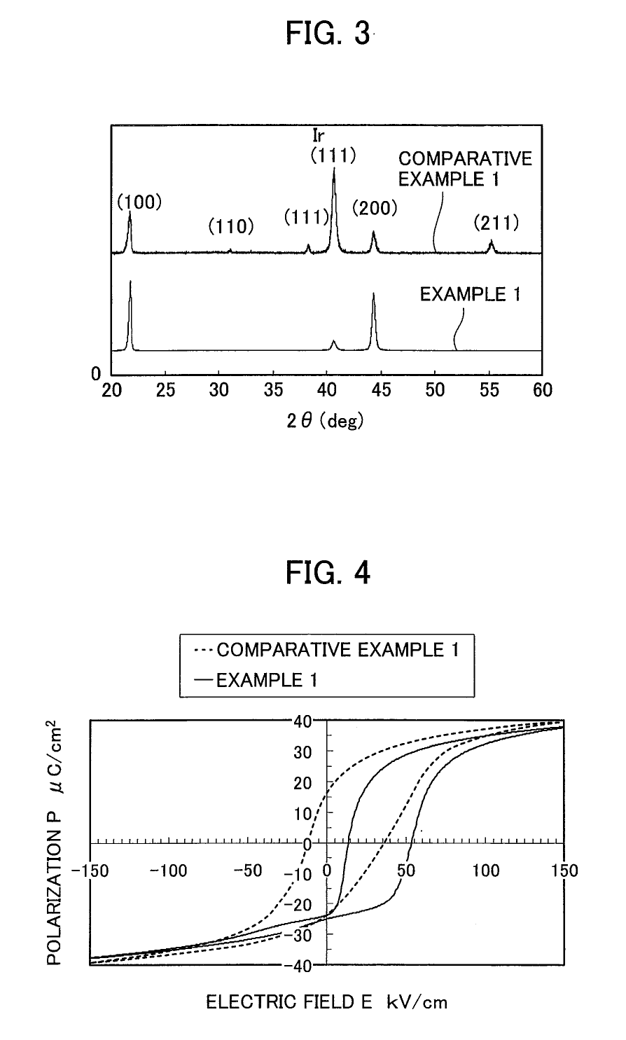

The results are shown in FIG. 3, which is a graph showing the results of X-ray diffractometry obtained in Example 1 and Comparative Example 1 as described later.

On the PZT film as above which has been formed on the lower electrode, a 100 nm-thick layer of Pt was formed by sputtering as an upper electrode so as to obtain a piezoelectric device.

The hysteresis characteristics of the PZT film in the piezoelectric device were studied using a ferroelectric hysteresis evaluation system FCE from TOYO Corporation. The results are shown in FIG. 4.

From the hysteresis characteristics as shown in FIG. 4, the shift of hysteresis D (%) of the PZT film was found to be 170%, which is set forth in Table 1.

How to find the shift of hysteresis D (%) has already been described.

### Comparative Example 1

Following the same procedure as Example 1 except for a film deposition temperature of 450° C., a PZT film was obtained.

The thickness and lead amount of the PZT film were found in the same manner as Example 1. The PZT film had a thickness of 4 μm, and the molar ratio of lead as a cation to other cations in the film was 1.04. The results are also summarized in Table 1.

Moreover, the PZT film was subjected to the X-ray diffractometry in the same manner as Example 1. The results are shown in FIG. 3.

The hysteresis characteristics of the PZT film studied in the same manner as Example 1 were as shown in FIG. 4. The shift of hysteresis D (%) of the PZT film found from FIG. 4 was 45%, which is also set forth in Table 1.

It is seen from the results summarized in Table 1 and shown in FIG. 4 that, in the case of the PZT film of Example 1, the molar ratio of lead as a cation to other cations was 1.12, a value larger than 1.07 indicating the presence of excess lead, two coercive fields Ec₁ and Ec₂ in the hysteresis characteristics were both positive, and the shift of hysteresis D was 170%, that is to say, more than 100%. In contrast, in the case of the PZT film of Comparative Example 1, the molar ratio of lead as a cation to other cations was 1.04, that is to say, less than 1.07, one of two coercive fields in the hysteresis characteristics was negative and the other was positive, and the shift of hysteresis D was 45%, that is to say, less than 100%.

It was confirmed from the graph of FIG. 3 showing the results of X-ray diffractometry that the PZT film of Example 1 was (100)-oriented.

As to the PZT film of Comparative Example 1, it was confirmed that the (100) orientation was predominant in the film, whereas other orientations were also present.

The PZT film of Example 1 according to the present invention was thus confirmed to be (100)-oriented and have an XRD perovskite single phase, so that it proved to be a PZT film substantially free of impurities.

In other words, it has been revealed from the results shown in Table 1 as well as FIGS. 3 and 4 that the PZT film of Example 1 according to the present invention was the PZT film which was over 2 μm thick, exhibited such hysteresis characteristics that two coercive fields were both positive, whose lead amount, namely molar ratio of lead to other cations in the film, was 1.07 or more, which had principally (100) orientation, had a perovskite single phase with substantially no pyrochlore phases, and which was substantially free of impurities.

The effects of the present invention are evident from the results obtained in the above examples.

What is claimed is:

1. A lead-containing perovskite-type oxide film having principally (100) and/or (001) orientation and containing lead as a chief component, which is over 2 μm thick and exhibits such hysteresis characteristics that two coercive fields are both positive.

2. The lead-containing perovskite-type oxide film according to claim 1, wherein a molar ratio of lead to other cations in said oxide film is 1.07 or more, and substantially no impurity phase is detected in said oxide film by θ/2θ X-ray diffractometry.

3. A lead-containing perovskite-type oxide film having principally (100) and/or (001) orientation and containing lead as a chief component, wherein:
the oxide film exhibits such hysteresis characteristics that two coercive fields are both positive;
a molar ratio of lead to other cations in the oxide film is 1.07 or more; and
substantially no impurity phase is detected in the oxide film by θ/2θ X-ray diffractometry.

4. The lead-containing perovskite-type oxide film according to claim 1, wherein said oxide film is deposited on a substrate of one of silicon and silicon oxide.

5. The lead-containing perovskite-type oxide film according to claim 1, wherein said oxide film has 90% or more of said (100) and/or (001) orientation.

6. The lead-containing perovskite-type oxide film according to claim 1, wherein said oxide film contains Pb, Zr, Ti, and O.

7. The lead-containing perovskite-type oxide film according to claim 1, wherein said oxide film is a thin film of a material represented by a chemical formula:
Pbₓ(Zr_{1-y},Ti_{y})_{1-z}Nb_{z}O_{δ}
[where Pb is a site A element, Zr, Ti and Nb are site B elements, and x is a molar ratio of lead to other cations in said oxide film], and x, y, and z in the formula are defined as 1.07≦x, 0≦y≦1, and 0≦z≦0.25, respectively.

8. The lead-containing perovskite-type oxide film according to claim 7, wherein x, y, and z in said chemical formula Pbₓ(Zr_{1-y},Ti_{y})_{1-z}Nb_{z}O_{δ} are defined as 1.07≦x, 0.4≦y≦0.6, and 0.1≦z≦0.2, respectively.

9. A method of producing a lead-containing perovskite-type oxide film, which comprises controlling upon production of the lead-containing perovskite-type oxide film according to claim 1 a molar ratio of lead to other cations in said oxide film during film deposition.

10. The method of producing a lead-containing perovskite-type oxide film according to claim 9, wherein a lead-containing perovskite-type oxide film is deposited by sputtering.

11. The method of producing a lead-containing perovskite-type oxide film according to claim 9, wherein said molar ratio of lead is controlled by adjusting a film deposition temperature during film deposition.

12. The method of producing a lead-containing perovskite-type oxide film according to claim 9, wherein said molar ratio of lead is controlled by adjusting plasma energy applied to a substrate for film deposition during film deposition.

13. The method of producing a lead-containing perovskite-type oxide film according to claim 9, wherein said molar ratio of lead is controlled by adjusting a partial pressure of oxygen during film deposition.

14. The method of producing a lead-containing perovskite-type oxide film according to claim 9, wherein said molar ratio of lead is controlled by adjusting a power supplied during film deposition.

15. The method of producing a lead-containing perovskite-type oxide film according to claim 9, wherein said molar ratio of lead is controlled by adjusting a film deposition pressure during film deposition.

16. A piezoelectric device comprising:
a piezoelectric member constituted by the lead-containing perovskite-type oxide film according to claim 1; and
a lower electrode and an upper electrode formed on lower and upper sides of the piezoelectric member, respectively, in order to apply voltages to the piezoelectric member,
the lead-containing perovskite-type oxide film as the piezoelectric member having a lead amount near an interface with the lower electrode that is equal to or larger than a mean lead amount of the oxide film as a whole.

17. A liquid ejecting apparatus comprising:
the piezoelectric device according to claim 16;
a liquid reservoir for storing liquid; and
a liquid spout through which the liquid in the liquid reservoir is ejected to outside by applying a voltage to the piezoelectric device.
